(19) United States
(12) Patent Application Publication
(10) Pub. No.: US 2002/0086497 A1
(43) Pub. Date: Jul. 4, 2002

(54) Beaker shape trench with nitride pull-back for STI

(76) Inventor: Siang Ping Kwok, Dallas, TX (US)

Correspondence Address: TEXAS INSTRUMENTS INCORPORATED, P O BOX 655474, M/S 3999, DALLAS, TX, 75265

(21) Appl. No.: 10/006,574

(22) Filed: Dec. 6, 2001

Related U.S. Application Data
(60) Provisional application No. 60/259,399, filed on Dec. 30, 2000.

(51) Int. Cl. H01L 21/8238; H01L 21/76

(52) U.S. Cl. 438/424; 438/426; 438/425

(57) ABSTRACT

Shallow trench isolation is improved by adding sacrificial sidewalls to the nitride mask, which are subsequently removed to allow gap fill oxide material to overlap the edges of the active region, preventing CMP-induced trenching at the edges of the active area.

### BACKGROUND AND SUMMARY OF THE INVENTION

The present invention relates to integrated circuit structures and fabrication methods, and particularly to formation of shallow trench isolation.

### BACKGROUND

Shallow trench isolation is a means of isolating integrated circuit components that involves forming a trench between the devices to be isolated, and filling that trench with a non-conductive material, such as an oxide. STI significantly shrinks the area needed to isolate transistors while offering protection from latch-up.

STI offers challenges in providing void-free, seamless gapfill by CVD (chemical vapor deposition) and uniform planarization by CMP (chemical mechanical polish). The basic process silicon etch, oxidation, trench fill by CVD and CMP. Many processes begin with deposition of a pad oxide and a nitride layer used as a polish stop for the CMP, followed by etching of the dielectrics and the silicon. After trench etch, a liner oxide is grown and the trench is filled by CVD. the structure is then planarized by CMP. The nitride and oxide layers are then removed by wet etch, followed by other process steps leading to gate formation and other front end processing.

Nitride Pull-Back for STI

The present application discloses an improvement to the formation of shallow trench isolation. A nitride “pull-back” is formed by adding a sidewall oxide to the nitride mask and using the nitride with its sidewall as the mask for etching of silicon shallow trench. Subsequently the sidewall oxide is removed (e.g. by wet oxide etch), resulting in the nitride “pull-back” from the edges of the silicon. A thin oxide liner is then grown at the edges of the silicon trench, and subsequently a gap filling oxide is deposited to fill the trench and over the nitride. The nitride pull-back allows the trench fill oxide to overlap the silicon active areas. After completion of CMP (chemical mechanical polishing), the nitride strip and removal of pad oxide underneath the nitride, the cap fill oxide overlap provides process margin to avoid oxide trenching below the silicon (divot) at the edges of the active area and subsequent poly wraparound problem.

The nitride pull-back is formed by adding sacrificial oxide sidewalls to the nitride.

Advantages of the disclosed methods and structures, in various embodiments, can include one or more of the following:

avoids poly wraparound;

decreases oxide gap formation between oxide and silicon;

greater control of nitride sidewall formation relative to silicon trench width;

avoids voids or seams in the gap filling oxide at center of STI;

avoids divot in gap fill oxide at the edge of the silicon;

precise control of the amount of nitride pull-back by the sidewall thickness.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows a flow chart for implementing the preferred embodiment.

FIG. 2 shows a prior art STI with corner recesses.

FIG. 3 shows a partially fabricated integrated circuit structure.

FIG. 4 shows a partially fabricated integrated circuit structure.

FIG. 5 shows a partially fabricated integrated circuit structure.

FIG. 6 shows a partially fabricated integrated circuit structure.

FIG. 7 shows a partially fabricated integrated circuit structure.

FIG. 8 shows a partially fabricated integrated circuit structure.

FIG. 9 shows a partially fabricated integrated circuit structure.

FIG. 10 shows a partially fabricated integrated circuit structure.

FIG. 11 shows a partially fabricated integrated circuit structure.

FIG. 12 shows a partially fabricated integrated circuit structure.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

The preferred embodiment of the innovations of the present application are described in the context of a shallow trench isolation process. Though the specific materials and steps for the preferred embodiment are described, it will be understood to those skilled in the relevant art that substitutions can be made and that individual process steps may be added or omitted and still be within the contemplation of the present application. Likewise, the innovations herein disclosed may be applicable to uses other than those described and still be within the contemplation of the present application.

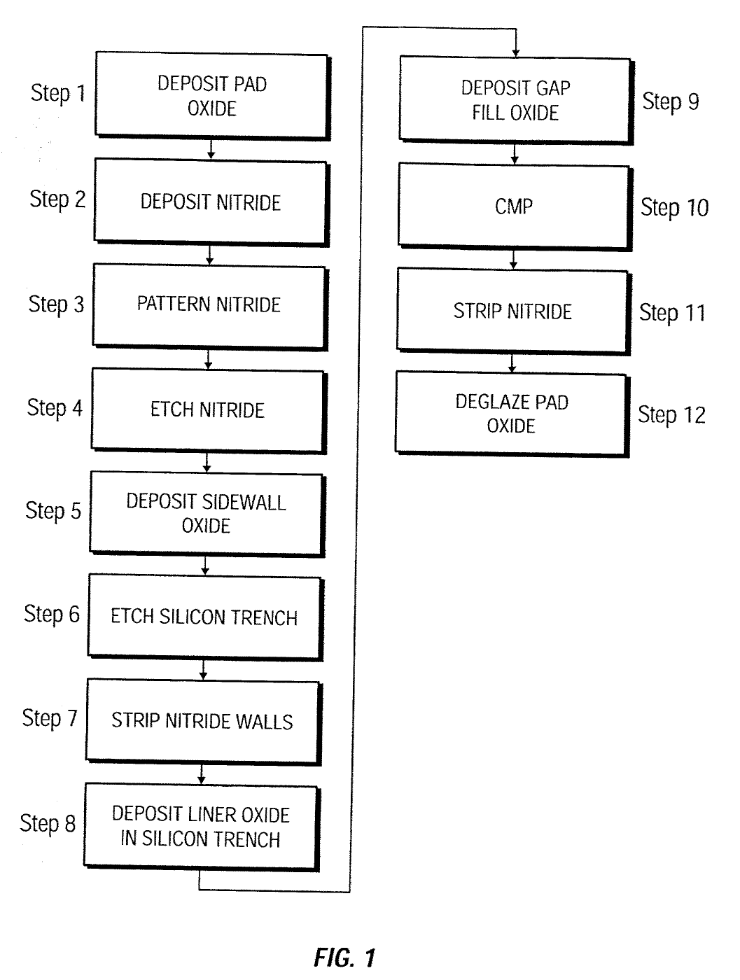

FIG. 1 shows a possible flow chart for implementing the preferred embodiment. A silicon substrate is covered by growing a thin layer of silicon dioxide (often referred to as a pad oxide) (step 1). The pad oxide is on the order of 10-20 nm thick. A thicker layer of nitride (about 100-200 nm thick) is deposited by CVD on the pad oxide (step 2). A trench is patterned using photolithography (step 3) and the nitride is etched, stopping at the oxide (step 4). The width of this first trench is slightly wider than the trench that will later be etched for the STI. The photoresist is removed.

A layer of silicon dioxide is deposited from a TEOS (tetraethyl orthosilicate) source using a hotwall LPCVD system (step 5). This layer is about 20 nm thick on each side of the nitride sidewalls. The oxide is etched leaving only sidewalls at the edges of the nitride. The silicon trench is then etched using the nitride and its sidewall as etching masks (step 6).

Next, the oxide sidewalls are wet stripped to create a slight nitride pull-back at the surface of the silicon and a slight undercut of pad oxide beneath the nitride (step 7). (Note that in the preferred embodiment, the pad oxide is also etched in this step.) A thin layer of silicon dioxide is grown on the silicon sidewalls of the trench, sometimes called a liner (step 8). The gap fill oxide is then deposited by CVD to a depth of several hundred nanometers (step 9). The oxide fills between the nitride walls and over the pull-back, as shown in FIG. 9. The oxide is then planarized using CMP, stopping at the nitride (step 10).

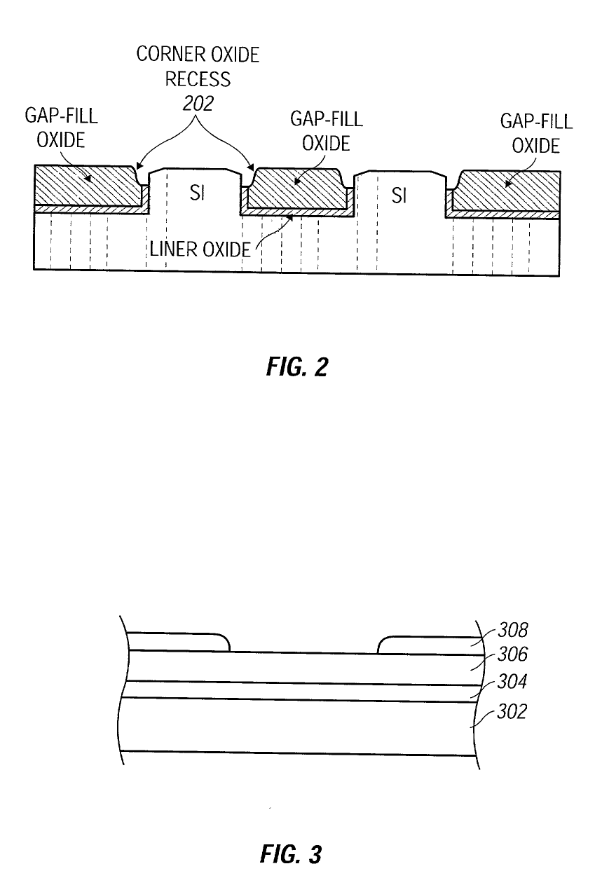

Next, the nitride is stripped (step 11), and the pad oxide is deglazed (step 12), exposing the surface of the active region. Because the nitride was set back from the edge of the silicon trench (by the thickness of the oxide sidewall), the gap fill oxide protrudes above the edge of the trench, providing process margin to avoid oxide trenching below the level of the silicon at the edges of the active area. FIG. 2 shows a STI trench oxide recess 202 at the corners of the active silicon areas, which causes gate oxide integrity (GOI) and subthreshold kink problems.

Voids and defects between the silicon and the gap fill dielectric are avoided using this innovative technique. By etching the nitride trench wider than the STI, a controlled protruding wall for trench liner oxidation is formed, reducing voids in the trench oxide.

The thickness of the oxide sidewall, and thus the distance of setback, may be more precisely controlled than in other methods of sidewall setback formation (such as selective and isotropic nitride etch). As device sizes shrink (for instance, as trench widths are reduced to 0.15 micron or less) the ability to precisely control the protrusion of the silicon wall prior to liner oxidation to avoid gap fill oxide voids with minimal encroachment will become increasingly important.

FIGS. 3-12 show a partially fabricated integrated circuit employing the present innovations at various stages of the process.

FIG. 3 shows a partially fabricated integrated circuit structure at a preliminary stage of the STI process. A silicon (or other semiconductor) substrate 302 is covered with a thin layer of silicon dioxide 304, which is covered by a thicker layer of nitride 306. The nitride 306 is patterned with a layer of photoresist 308.

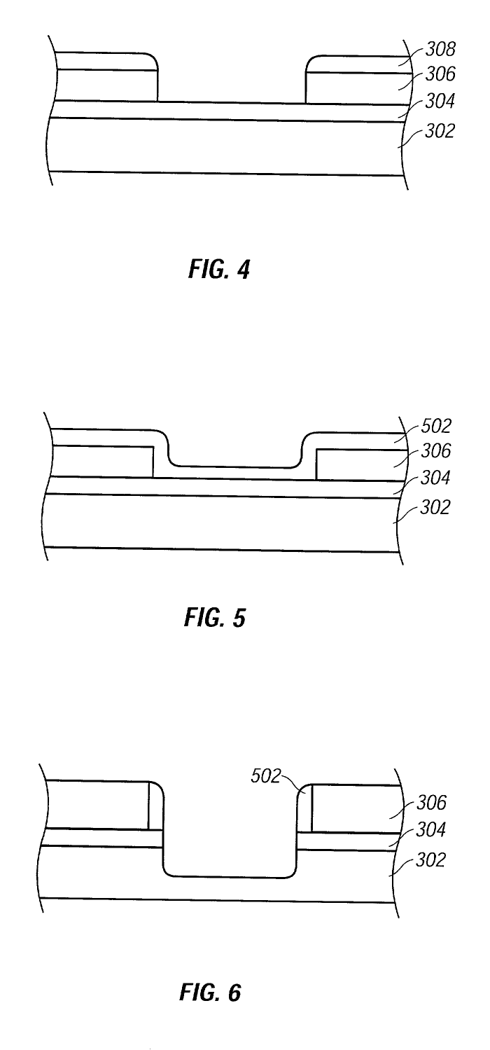

FIG. 4 shows the structure after the nitride 306 has been etched, with the silicon substrate 302 covered by the pad oxide 304. The nitride 306 has been etched, forming a trench where the resist 308 exposed the nitride surface. The resist 308 is then removed.

FIG. 5 shows the structure after an oxide layer 502 has been deposited on the nitride 306, forming sidewalls of oxide 502 on the sides of the nitride pads. This oxide 502 is preferably deposited using a TEOS source.

FIG. 6 shows the structure after the silicon trench has been etched. Note that the trench in the silicon 302 is wider than the distance between the nitride pads because of the oxide-nitride sidewalls 502. This difference of dimension will later provide the setback.

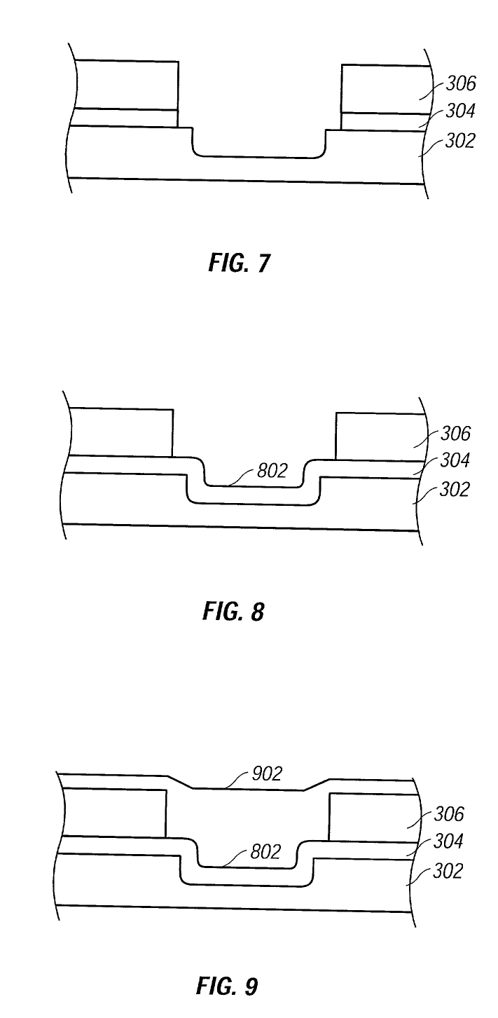

FIG. 7 shows the structure after the oxide sidewalls have been stripped from the nitride pads 306, forming the setback, or beaker shaped trench.

FIG. 8 shows the structure after the growth of the liner oxide 802 on the bottom and sidewalls of the silicon trench. Note that the growth of the liner oxide has slightly softened the semiconductor corners at the trench edge.

FIG. 9 shows the structure after the gap fill oxide 902 has been deposited. The gap fill oxide 902 fills the silicon trench and the space between the nitride pads, as well as above the nitride pads. Note the overlap of the cap oxide 902 around the corner of the silicon trench. This oxide is deposited using CVD.

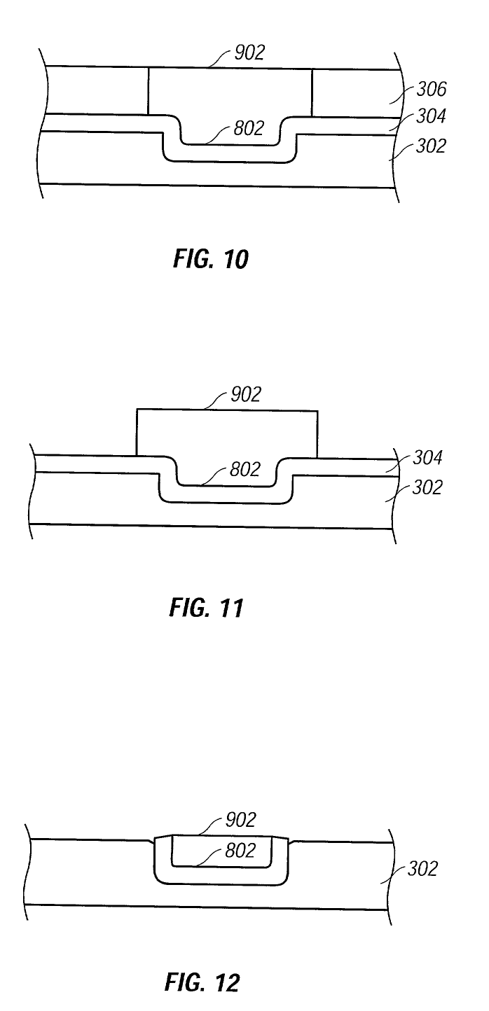

FIG. 10 shows the structure after CMP. The polish stops at the nitride.

FIG. 11 shows the structure after the nitride has been stripped (preferably using a HF wet strip). This leaves the STI with the gap fill oxide 902 over the edges of the trench.

FIG. 12 shows the structure after the pad oxide 304 has been deglazed.

The oxide thickness on the nitride sidewalls precisely controls the silicon protrusion. Stripping of the oxide sidewall is incorporated into pad oxide undercut etch for corner rounding. The protruding silicon wall and the pad oxide undercut help silicon corner rounding during thin liner oxidation and help minimize encroachment of the silicon moat.

According to a disclosed class of innovative embodiments, there is provided: A method for fabricating trench isolation, comprising the steps of: A) forming a patterned oxidation-resistant mask layer on a semiconductor body, and forming sidewall spacers on said mask layer; B) etching a trench into exposed portions of said body; C) removing said spacers from said mask layer, and then growing a liner oxide on all exposed semiconductor material; D) depositing a filler dielectric overall, and polishing back said filler dielectric to expose said nitride; and E) removing said nitride, and polishing back the remainder of said filler dielectric, to expose portions of said semiconductor body outside said trench; whereby said step C) causes said filler dielectric to be wider than said trench, and thereby avoids trenching of said filler dielectric at the completion of said step E). According to another disclosed class of innovative embodiments, there is provided a product made by this method.

According to another disclosed class of innovative embodiments, there is provided: A method for fabricating trench isolation, comprising the steps of: 1) forming a patterned nitride layer, with sidewall spacers of a different material, on a semiconductor body; 2) etching a trench into exposed portions of said body; 3) stripping said spacers; 4) growing a liner oxide on all exposed semiconductor material; 5) depositing a filler dielectric overall; 6) polishing back said filler dielectric to expose said nitride; 7) removing said nitride; and 8) polishing back the remainder of said filler dielectric, to expose said semiconductor body; whereby said step 3) causes said filler dielectric, as deposited by said step 5), to be wider than said trench, and thereby prevents marginal voids in said filler dielectric at the completion of said step 8). According to another disclosed class of innovative embodiments, there is provided a product made by this method.

According to another disclosed class of innovative embodiments, there is provided: A method for fabricating trench isolation, comprising the steps of: a) forming a pad oxide layer on a semiconductor body, and forming a nitride layer on said pad oxide layer; b) etching a first trench into said nitride layer, said trench having nitride sidewalls; c) forming oxide spacers on said nitride sidewalls; d) etching a second trench into said body in the location of said first trench, said second trench having semiconductor sidewalls and being narrower than said first trench; e) stripping said oxide spacers to expose semiconductor surface around said second trench, in a setback between said nitride sidewalls and said semiconductor sidewalls; f) growing a liner oxide on all exposed semiconductor material; g) depositing a filler dielectric overall, and polishing back said filler dielectric to expose said nitride; and h) removing said nitride, and polishing back the remainder of said filler dielectric, to expose said semiconductor body at locations outside said second trench; whereby said step e) causes said filler dielectric to extend into said setback before step h), and thereby avoids trenching of said filler dielectric at the completion of said step h). According to another disclosed class of innovative embodiments, there is provided a product made by this method.

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

The listed process steps for the preferred embodiment are not intended to limit the scope of the inventions herein disclosed. Process steps may be added or eliminated without deviating from the contemplation of the present application. Likewise, the process itself may be applicable in other circumstances than those mentioned specifically in this application.

The innovative pull-back formation can be applied to other process areas besides STI. For example, where a step juncture is desired between two levels of different material, the present innovations may be applicable.

The specific materials mentioned in the preferred embodiment need not be used, as other materials may be found that serve the same function in the innovative process. Such substitutions are within the contemplation of the present application.

Additional general background, which help to show the knowledge of those skilled in the art regarding variations and implementations of the disclosed inventions, may be found in the following documents, all of which are hereby incorporated by reference: Coburn, PLASMA ETCHING AND REACTIVE ION ETCHING (1982); HANDBOOK OF PLASMA PROCESSING TECHNOLOGY (ed. Rossnagel); PLASMA ETCHING (ed. Manos and Flamm 1989); PLASMA PROCESSING (ed. Dieleman et al. 1982); Schmitz, CVD OF TUNGSTEN AND TUNGSTEN SILICIDES FOR VLSI/ULSI APPLICATIONS (1992); METALLIZATION AND METAL-SEMICONDUCTOR INTERFACES (ed. Batra 1989); VLSI METALLIZATION: PHYSICS AND TECHNOLOGIES (ed. Shenai 1991); Murarka, METALLIZATION THEORY AND PRACTICE FOR VLSI AND ULSI (1993); HANDBOOK OF MULTILEVEL METALLIZATION FOR INTEGRATED CIRCUITS (ed. Wilson et al. 1993); Rao, MULTILEVEL INTERCONNECT TECHNOLOGY (1993); CHEMICAL VAPOR DEPOSITION (ed. M. L. Hitchman 1993); and the semiannual conference proceedings of the Electrochemical Society on plasma processing.

What is claimed is:

1. A method for fabricating trench isolation, comprising the steps of:
A) forming a patterned oxidation-resistant mask layer on a semiconductor body, and forming sidewall spacers on said mask layer;
B) etching a trench into exposed portions of said body;
C) removing said spacers from said mask layer, and then growing a liner oxide on all exposed semiconductor material;
D) depositing a filler dielectric overall, and polishing back said filler dielectric to expose said nitride; and
E) removing said nitride, and polishing back the remainder of said filler dielectric, to expose portions of said semiconductor body outside said trench;
whereby said step C) causes said filler dielectric to be wider than said trench, and thereby avoids trenching of said filler dielectric at the completion of said step E).

2. The method of claim 1, wherein said semiconductor body consists essentially of silicon.

3. The method of claim 1, wherein said mask layer consists essentially of silicon nitride over a pad oxide layer consisting of silicon dioxide.

4. The method of claim 1, wherein said filler dielectric consists essentially of silicon dioxide.

5. The method of claim 1, wherein said filler dielectric is more than three times as thick as said liner oxide.

6. The method of claim 1, wherein said liner oxide consists of silicon dioxide.

7. A method for fabricating trench isolation, comprising the steps of:
1) forming a patterned nitride layer, with sidewall spacers of a different material, on a semiconductor body;
2) etching a trench into exposed portions of said body;
3) stripping said spacers;
4) growing a liner oxide on all exposed semiconductor material;
5) depositing a filler dielectric overall;
6) polishing back said filler dielectric to expose said nitride;
7) removing said nitride; and
8) polishing back the remainder of said filler dielectric, to expose said semiconductor body;
whereby said step 3) causes said filler dielectric, as deposited by said step 5), to be wider than said trench, and thereby prevents marginal voids in said filler dielectric at the completion of said step 8).

8. The method of claim 7, wherein said semiconductor body consists essentially of silicon.

9. The method of claim 7, wherein said nitride layer overlies a pad oxide layer grown from said body.

10. The method of claim 7, wherein said semiconductor body consists essentially of silicon, and wherein said nitride layer overlies a silicon dioxide pad oxide layer grown from said body.

11. The method of claim 7, wherein said filler dielectric consists essentially of silicon dioxide.

12. The method of claim 7, wherein said filler dielectric is more than three times as thick as said liner oxide.

13. The method of claim 7, wherein said liner oxide consists of silicon dioxide.

14. A method for fabricating trench isolation, comprising the steps of:
a) forming a pad oxide layer on a semiconductor body, and forming a nitride layer on said pad oxide layer;
b) etching a first trench into said nitride layer, said trench having nitride sidewalls;
c) forming oxide spacers on said nitride sidewalls;
d) etching a second trench into said body in the location of said first trench, said second trench having semiconductor sidewalls and being narrower than said first trench;
e) stripping said oxide spacers to expose semiconductor surface around said second trench, in a setback between said nitride sidewalls and said semiconductor sidewalls;
f) growing a liner oxide on all exposed semiconductor material;
g) depositing a filler dielectric overall, and polishing back said filler dielectric to expose said nitride; and
h) removing said nitride, and polishing back the remainder of said filler dielectric, to expose said semiconductor body at locations outside said second trench;
whereby said step e) causes said filler dielectric to extend into said setback before step h), and thereby avoids trenching of said filler dielectric at the completion of said step h).

15. The method of claim 14, wherein said semiconductor body consists essentially of silicon.

16. The method of claim 14, wherein said filler dielectric consists essentially of silicon dioxide.

17. The method of claim 14, wherein said filler dielectric is more than three times as thick as said liner oxide.

18. The method of claim 14, wherein said liner oxide consists of silicon dioxide.

19. A product produced by the method of claim 1.

20. A product produced by the method of claim 17.

21. A product produced by the method of claim 14.
